(19) United States
(12) Patent Application Publication
(10) Pub. No.: US 2022/0166186 A1
(43) Pub. Date: May 26, 2022

(54) SEMICONDUCTOR LASER ELEMENT

(71) Applicant: Panasonic Corporation, Osaka (JP)

(72) Inventor: Hiroyuki Hagino, Osaka (JP)

(21) Appl. No.: 17/442,119

(22) PCT Filed: Feb. 13, 2020
(86) PCT No.: PCT/JP2020/005427

§ 371 Date: Sep. 22, 2021

(30) Foreign Application Priority Data
Mar. 25, 2019 (JP) 2019-056899

(51) Int. Cl. H01S 5/024; H01S 5/343; H01S 5/0234; H01S 5/042

(52) U.S. Cl. CPC H01S 5/02461; H01S 5/04256; H01S 5/0234; H01S 5/34333

(57) ABSTRACT

A semiconductor laser element includes: a first semiconductor layer of a first conductive type; an emission layer which is arranged above the first semiconductor layer; a second semiconductor layer of a second conductive type which is arranged above the emission layer and includes a waveguide part through which light generated at the emission layer is transmitted; a p-side electrode which is arranged above the waveguide part; a base which is arranged oppositely to the p-side electrode; a conductive member which is arranged between the p-side electrode and the base; and a void part which is arranged in an inner region of the conductive member and has higher thermal resistance than the conductive member.

### CROSS-REFERENCE OF RELATED APPLICATIONS

This application is the U.S. National Phase under 35 U.S.C. § 371 of International Patent Application No. PCT/JP2020/005427, filed on Feb. 13, 2020, which in turn claims the benefit of Japanese Application No. 2019-056899, filed on Mar. 25, 2019, the entire disclosures of which Applications are incorporated by reference herein.

### TECHNICAL FIELD

The present disclosure relates to a semiconductor laser element.

Note that the present application is a patent application subject to Article 17 in Industrial Technology Enhancement Act for contract research “Development of high-brightness and high-efficiency next-generation laser technologies/Development of new light source and element technologies for next-generation machining/Development of GaN-based high-output, high-beam quality semiconductor laser for high-efficiency machining” in 2016 by National research and development agency New Energy and Industrial Technology Development Organization.

### BACKGROUND ART

In recent years, semiconductor laser elements have been attracting attention as light sources for various applications, for example, light sources for image display devices such as displays and projectors, light sources for in-vehicle head lamps, light sources for industrial lighting and consumer lighting, or light sources for industrial equipment such as laser welding equipment, thin film annealing equipment, and laser processing equipment. There have also been demands on the semiconductor laser elements used as the light sources for the aforementioned purposes for achieving higher light output largely exceeding one watt and high beam quality.

To realize the high beam quality, it is desirable that laser light oscillate in a fundamental transverse mode. To realize the fundamental transverse mode operation, there is a method for reducing the width of a waveguide and performing operation in a state in which a higher mode is not optically present (a cut-off state). However, a greater waveguide width (wide stripe) is more effective for higher output, and thus the transverse mode of the laser light is a higher mode on a high-output semiconductor laser element whose light output exceeds one watt in many cases.

Patent Literature (PTL) 1 discloses a conventional semiconductor laser element. FIG. 10 is a schematic sectional view illustrating a configuration of the conventional semiconductor laser element disclosed in PTL 1.

As illustrated in FIG. 10, the conventional semiconductor laser element mainly includes: substrate 1010, n-side clad layer 1012, active layer 1018, p-side clad layer 1024, p-side contact layer 1026, p-side electrode 1028, pad electrode 1030, and n-side electrode 1036. P-side clad layer 1024 has ridge part 1040 and non-ridge part 1042. P-side electrode 1028 of the semiconductor laser element illustrated in FIG. 10 has void part 1032 without any conductive material provided between an upper region of ridge part 1040 and an upper region of non-ridge part 1042. It is described that since a heat dissipation path is separated from the vicinity of an emission point in active layer 1018 by void part 1032 described above, a temperature difference between ridge part 1040 and non-ridge part 1042 can be reduced, as a result of which a horizontal transverse mode can be stabilized.

### CITATION LIST

### Patent Literature

[PTL 1] Japanese Unexamined Paten Application Publication No. 2007-109886

### SUMMARY OF INVENTION

### Solution to Problem

A method described in PTL 1 is effective for a structure in which a waveguide width for maintaining the fundamental transverse mode is reduced by cut-off. However, with the aforementioned wide stripe structure in which the waveguide width is widened for the purpose of higher output, a large number of high horizontal transverse modes is optically permitted in the waveguide, which therefore results in failure to suppress a higher horizontal transverse mode even when a temperature difference between ridge part 1040 and non-ridge part 1042 is reduced, as in PTL 1.

It is an object of the present disclosure to provide a semiconductor laser element capable of improving the ratio of a fundamental transverse mode in laser light even during high output operation.

### Solution to Problem

To address the object described above, a semiconductor laser element according to one aspect of the present disclosure includes: a first semiconductor layer of a first conductive type; an emission layer which is arranged above the first semiconductor layer and formed of a semiconductor; a second semiconductor layer of a second conductive type which is arranged above the emission layer and includes a waveguide part through which light generated at the emission layer is transmitted; an electrode which is arranged above the waveguide part; a base which is arranged oppositely to the electrode; a conductive member which is arranged between the electrode and the base; and a void part which is arranged in an inner region of the conductive member and has higher thermal resistance than the conductive member.

As described above, since refractive index distribution where the fundamental transverse mode is preferential can be formed at the waveguide part by the void part, it is possible to increase the ratio of the fundamental transverse mode in laser light even during high output operation.

In the semiconductor laser element according to one aspect of the present disclosure, the second semiconductor layer may further include a flat part which is arranged adjacently to the waveguide part, and the waveguide part may be projected from the flat part in a direction away from the emission layer.

Consequently, it is possible to confine the light in the waveguide part.

In the semiconductor laser element according to one aspect of the present disclosure, a width of the void part may be smaller than a width of the waveguide part.

Consequently, since the void part is not located on a heat dissipation path from the end part of the waveguide part in a width direction, it is possible to provide a large temperature difference between the central part and the end part of the waveguide part in the width direction. That is, it is possible to provide a large refractive index difference between the central part and the end part of the waveguide part in the width direction.

In the semiconductor laser element according to one aspect of the present disclosure, the width of the void part may be greater than or equal to 0.375 times and less than or equal to 0.625 times the width of the waveguide part.

Consequently, the ratio of the fundamental transverse mode is even more increased and high laser light output intensity is obtained.

The semiconductor laser element according to one aspect of the present disclosure may further include: a front side end surface which is one of end surfaces in a transmission direction of the light and from which the light is emitted; and a rear side end surface which is another one of the end surfaces in the transmission direction of the light and has higher reflectance of the light than the front side end surface, in which the width of the void part may increase with a decrease in distance from the front side end surface.

As described above, providing the void part at a position near the front side end surface with relatively high light density makes it possible to effectively control the transverse mode. Moreover, providing no void part at a position near the rear side end surface with relatively low light density (or reducing the width of the void part) makes it possible to ensure the heat dissipation performance.

In the semiconductor laser element according to one aspect of the present disclosure, the void part may be formed of air.

Consequently, it is possible to realize a void part which has higher thermal resistance than the conductive member and is capable of reducing stress attributable to a thermal expansion coefficient difference from the conductive member.

In the semiconductor laser element according to one aspect of the present disclosure, the void part may be arranged above a center of the electrode in a width direction.

Consequently, it is possible to bring the peak of distribution in the fundamental transverse mode and the peak of temperature distribution at the waveguide part into agreement with each other, which can promote operation in the fundamental transverse mode.

In the semiconductor laser element according to one aspect of the present disclosure, the void part may contact the electrode.

Consequently, it is possible to improve the effect of preventing heat dissipation from the electrode and the waveguide part by the void part.

The semiconductor laser element according to one aspect of the present disclosure may further include a solder layer which is arranged between the base and the conductive member, in which the void part may extend from the electrode to the solder layer.

In the semiconductor laser element according to one aspect of the present disclosure, the void part may contact the base.

### Advantageous Effects of Invention

The semiconductor laser element according to the present disclosure can increase the ratio of the fundamental transverse mode in laser light even during high output operation.

### BRIEF DESCRIPTION OF DRAWINGS

FIG. 1A is a plan view schematically illustrating a configuration of a semiconductor laser chip according to Embodiment 1.

FIG. 1B is a schematic sectional view illustrating the configuration of the semiconductor laser chip according to Embodiment 1.

FIG. 2A is a schematic sectional view illustrating a first step in a semiconductor laser chip manufacturing method according to Embodiment 1.

FIG. 2B is a schematic sectional view illustrating a second step in the semiconductor laser chip manufacturing method according to Embodiment 1.

FIG. 2C is a schematic sectional view illustrating a third step in the semiconductor laser chip manufacturing method according to Embodiment 1.

FIG. 2D is a schematic sectional view illustrating a fourth step in the semiconductor laser chip manufacturing method according to Embodiment 1.

FIG. 2E is a schematic sectional view illustrating a fifth step in the semiconductor laser chip manufacturing method according to Embodiment 1.

FIG. 2F is a schematic sectional view illustrating a sixth step in the semiconductor laser chip manufacturing method according to Embodiment 1.

FIG. 2G is a schematic sectional view illustrating a seventh step in the semiconductor laser chip manufacturing method according to Embodiment 1.

FIG. 2H is a schematic sectional view illustrating an eighth step in the semiconductor laser chip manufacturing method according to Embodiment 1.

FIG. 2I is a schematic sectional view illustrating a ninth step in the semiconductor laser chip manufacturing method according to Embodiment 1.

FIG. 2J is a schematic sectional view illustrating a tenth step in the semiconductor laser chip manufacturing method according to Embodiment 1.

FIG. 3A is a schematic plan view illustrating a configuration of a semiconductor laser element according to Embodiment 1.

FIG. 3B is a schematic sectional view illustrating the configuration of the semiconductor laser element according to Embodiment 1.

FIG. 4A is a view illustrating a heat dissipation path and electric field strength distribution of laser light in a fundamental transverse mode in the semiconductor laser element according to Embodiment 1.

FIG. 4B is a view illustrating calculation results of temperature distribution of a portion with a width W immediately below a waveguide part of an emission layer according to Embodiment 1.

FIG. 5 is a table illustrating thermal conductivity and thermal expansion coefficients of materials used for the semiconductor laser element and materials that can form a high thermal resistance part according to Embodiment 1.

FIG. 6A is a schematic sectional view illustrating a configuration of a semiconductor laser chip according to Embodiment 2.

FIG. 6B is a schematic sectional view illustrating the configuration of a semiconductor laser element according to Embodiment 2.

FIG. 7A is a schematic sectional view illustrating a first step in a semiconductor laser chip manufacturing method according to Embodiment 2.

FIG. 7B is a schematic sectional view illustrating a second step in the semiconductor laser chip manufacturing method according to Embodiment 2.

FIG. 7C is a schematic sectional view illustrating a third step in the semiconductor laser chip manufacturing method according to Embodiment 2.

FIG. 8A is a schematic sectional view illustrating a configuration of a semiconductor laser chip according to Embodiment 3.

FIG. 8B is a schematic sectional view illustrating a configuration of a sub-mount according to Embodiment 3.

FIG. 8C is a schematic sectional view illustrating a configuration of a semiconductor laser element according to Embodiment 3.

FIG. 9A is a schematic plan view illustrating a configuration of a semiconductor laser chip according to Embodiment 4.

FIG. 9B is a schematic sectional view illustrating the configuration of the semiconductor laser chip according to Embodiment 4.

FIG. 10 is a schematic sectional view illustrating a configuration of a conventional semiconductor laser element.

### DESCRIPTION OF EMBODIMENTS

Hereinafter, the embodiments of the present disclosure will be described with reference to the drawings. Note that the embodiments described below each form one detailed example of the present disclosure. Therefore, numerical values, shapes, materials, components, arrangement positions and connection modes of the components as well as steps, a sequence of the steps, etc. are each one example and are not intended to limit the present disclosure in any manner. Therefore, of the components of the embodiments below, those not described in any independent claim indicating a highest concept of the present disclosure will be described as optional components.

Each of the drawings is a schematic diagram and does not necessarily provide a precise illustration. Therefore, scales, etc. do not necessarily match in the drawings. Substantially the same configurations in each of the drawings will be provided with same signs and overlapping description thereof will be omitted or simplified.

Moreover, an X-axis, a Y-axis, and a Z-axis in the present description and drawings represent three axes of a three-dimensional orthogonal coordinate system. The X-axis and the Y-axis are orthogonal to each other and each orthogonal to the Z-axis.

In the present description, terms “above” and “below” do not refer to upward (vertically upward) and downward (vertically downward) directions in absolute spatial perception but are used as terms defined by relative positional relation based on lamination order in a laminated configuration. Moreover, the terms “above” and “below” are used not only when two components are spaced apart from each other and another component exists between the two components, but also when the two components are in contact with each other.

### Embodiment 1

A semiconductor laser element according to Embodiment 1 will be described.

### [Configuration of Semiconductor Laser Chip]

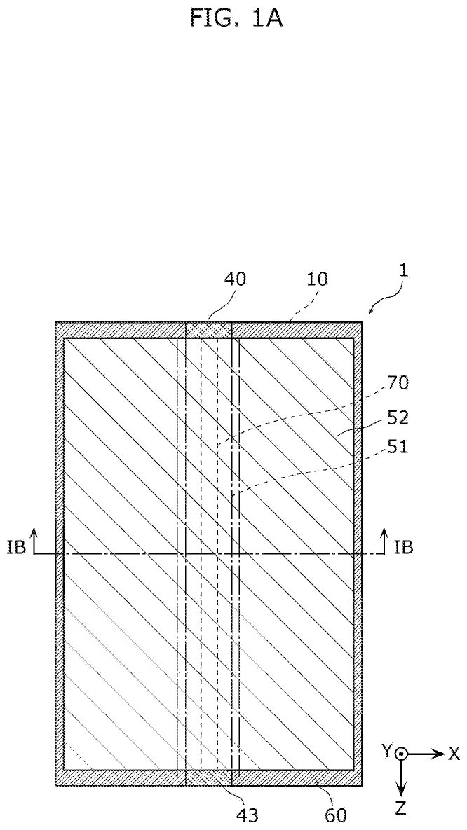

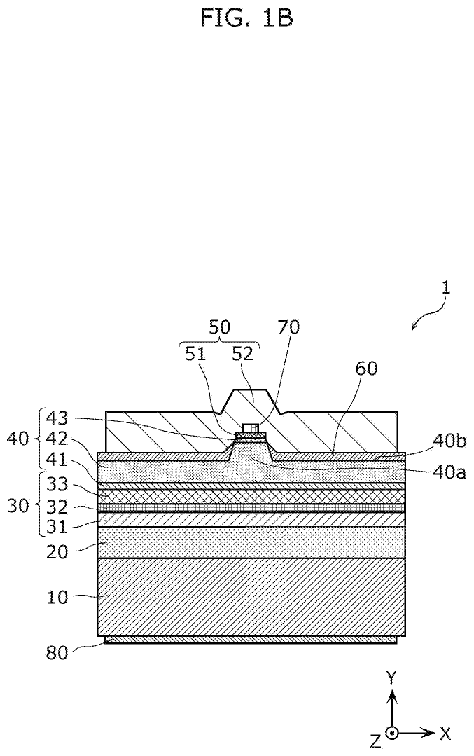

First, the configuration of a semiconductor laser chip as a component of the semiconductor laser element according to the present embodiment will be described with reference to FIGS. 1A and 1B. FIG. 1A is a schematic plan view illustrating the configuration of semiconductor laser chip 1 according to the present embodiment. FIG. 1A provides a plan view of substrate 10 of semiconductor laser chip 1. FIG. 1B is a schematic sectional view illustrating the configuration of semiconductor laser chip 1. FIG. 1B illustrates a cross section of semiconductor laser chip 1, taken along line IB-IB of FIG. 1A.

Semiconductor laser chip 1 according to the present embodiment is a semiconductor laser chip which is formed by a semiconductor material, and as illustrated in FIG. 1B, includes substrate 10, first semiconductor layer 20, emission layer 30, second semiconductor layer 40, electrode member 50, dielectric layer 60, high thermal resistance part 70, and n-side electrode 80.

Substrate 10 is a plate-like member with a main surface on which the semiconductor layers of semiconductor laser chip 1 are laminated. For example, substrate 10 is a GaN substrate. In the present embodiment, an n-type hexagonal GaN substrate having surface 0001 as a main surface is used as substrate 10.

First semiconductor layer 20 is a semiconductor layer of a first conductive type which is arranged above substrate 10. In the present embodiment, the first conductive type is an n type and first semiconductor layer 20 is, for example, an n-side clad layer formed of an n-type AlGaN.

Emission layer 30 is a layer which is arranged above first semiconductor layer 20 and formed of a semiconductor. In the present embodiment, emission layer 30 includes: n-side light guide layer 31 which is formed of n-type GaN; active layer 32 which is arranged above n-side light guide layer 31 and formed of an InGaN quantum well layer; and p-side light guide layer 33 which is arranged above active layer 32 and formed of p-type GaN, and emission layer 30 has a laminated structure in which the aforementioned layers are laminated on each other.

Second semiconductor layer 40 is a semiconductor layer of a second conductive type which is arranged above emission layer 30 and has waveguide part 40a through which light generated at emission layer 30 is transmitted. In the present embodiment, second semiconductor layer 40 further has flat part 40b which is arranged adjacently to waveguide part 40a. Waveguide part 40a is projected from flat part 40b in a direction away from emission layer 30. In other words, second semiconductor layer 40 has: waveguide part 40a which includes a ridged convex part extending in a laser resonator long direction (that is, a Y-axis direction in FIGS. 1A and 1B); and flat part 40b which widens in a horizontal direction (that is, an X-axis direction in FIG. 1B) from the root of waveguide part 40a (that is, the ridged portion near the side end part of emission layer 30). With such a configuration, light can be confined in waveguide part 40a. The second conductive type is a conductive type different from the first conductive type and a p-type in the present embodiment. In the present embodiment, second semiconductor layer 40 includes: electronic barrier layer 41 which is formed of AlGaN; p-side clad layer 42 which is arranged above electronic barrier layer 41 and formed of a p-type AlGaN layer; and p-side contact layer 43 which is arranged above p-side clad layer 42 and formed of p-type GaN. Second semiconductor layer 40 has a laminated structure in which the aforementioned layers are laminated on each other. P-side contact layer 43 is formed as a top layer (that is, a layer most distant from emission layer 30) of waveguide part 40a and is not formed on flat part 40b.

The width of waveguide part 40a (that is, a stripe width as the dimension in the laser resonator long direction and a direction perpendicular to the direction in which the semiconductor layers are laminated on each other) and the height of waveguide part 40a (the dimension in the direction in which the semiconductor layers are laminated on each other) are not specifically limited, and the width of waveguide part 40a is, for example, greater than or equal to 1 μm and less than or equal to 100 μm and the height of waveguide part 40a is greater than or equal to 100 nm and less than or equal to 1 μm. To operate semiconductor laser chip 1 with high optical output (for example, in a watt-class), the width of waveguide part 40a may be set to be greater than or equal to 10 μm and less than or equal to 50 μm and the height of waveguide part 40a may be set to be greater than or equal to 300 nm and less than or equal to 800 nm. In the present embodiment, the width is 10 μm and the height is 500 nm.

P-side clad layer 42 has a ridged convex part which extends in the laser resonator long direction. Ridged (that is, striped) waveguide part 40a is formed by the convex part of p-side clad layer 42 and p-side contact layer 43. Moreover, p-side clad layer 42 has a flat part as flat part 40b on both sides of waveguide part 40a. That is, the top surface of flat part 40b is a surface of p-side clad layer 42 and p-side contact layer 43 is not arranged on the top surface of flat part 40b.

Dielectric layer 60 is an insulating film which is formed of a dielectric formed on a side surface of waveguide part 40a in order to confine light. More specifically, dielectric layer 60 is continuously formed across the top surface of flat part 40b from the side surface of waveguide part 40a. In the present embodiment, dielectric layer 60 is continuously formed across the side surface of p-side contact layer 43, the side surface of the convex part of p-side clad layer 42, and the top surface of p-side clad layer 42 at the surroundings of waveguide part 40a.

The shape of dielectric layer 60 is not specifically limited, and dielectric layer 60 may be in contact with the side surface of waveguide part 40a and the top surface of flat part 40b. Consequently, it is possible to stably confine emitted light immediately below waveguide part 40a. In the present embodiment, dielectric layer 60 is formed of SiO₂.

Electrode member 50 is a conductive member which is formed above second semiconductor layer 40. Electrode member 50 is wider than waveguide part 40a. That is, the width of electrode member 50 (that is, the width in the X-axis direction) is greater than the width of waveguide part 40a (that is, the width in the X-axis direction). Electrode member 50 is in contact with the top surfaces of dielectric layer 60 and waveguide part 40a.

In the present embodiment, electrode member 50 has: p-side electrode 51 for current supply to waveguide part 40a; and pad electrode 52 which is arranged above p-side electrode 51.

P-side electrode 51 is one example of an electrode which is arranged above waveguide part 40a and is in contact with the top surface of waveguide part 40a. P-side electrode 51 is an ohmic electrode which makes ohmic contact with p-side contact layer 43 above waveguide part 40a, and p-side electrode 51 is in contact with the top surface of p-side contact layer 43 as the top surface of waveguide part 40a. For example, p-side electrode 51 is formed by use of metal materials such as Pd, Pt, and Ni. In the present embodiment, p-side electrode 51 has a two-layer structure which has a Pd layer and a Pt layer in order from second semiconductor layer 40 side.

Pad electrode 52 is one example of a conductive layer which is arranged above p-side electrode 51. Pad electrode 52 is wider than waveguide part 40a. Pad electrode 52 is also arranged above dielectric layer 60. In the present embodiment, pad electrode 52 is in contact with dielectric layer 60. That is, pad electrode 52 is formed so as to cover waveguide part 40a and dielectric layer 60. Pad electrode 52 is formed by use of metallic materials such as, for example, Ti, Ni, Pt, and Au. In the present embodiment, pad electrode 52 has a three-layer structure in which a Ti layer, a Pt layer, and an Au layer are laminated on each other in order from second semiconductor layer 40 side.

Note that pad electrode 52 is formed on an inner side of second semiconductor layer 40 in a plan view of pad electrode 52 as illustrated in FIG. 1A in order to improve the yield upon individualizing semiconductor laser chip 1 into pieces. That is, in a plan view of semiconductor laser chip 1, pad electrode 52 is not arranged at the periphery of semiconductor laser chip 1. That is, semiconductor laser chip 1 has a non-current injected region where no current is supplied to the periphery. Moreover, a sectional shape of the region where pad electrode 52 is formed has a structure as illustrated in FIG. 1B at any portion in the laser resonator long direction.

High thermal resistance part 70 is a void part which is arranged in a partial region between p-side electrode 51 and pad electrode 52 and has higher thermal resistance than pad electrode 52. High thermal resistance part 70 is a void part which is arranged in an inner region of pad electrode 52. In the present embodiment, high thermal resistance part 70 is in contact with p-side electrode 51.

The width of high thermal resistance part 70 in the X-axis direction is smaller than the width of p-side electrode 51 in the X-axis direction. In the present embodiment, high thermal resistance part 70 has lower thermal conductivity than p-side electrode 51 and pad electrode 52. Moreover, high thermal resistance part 70 may be formed of a material such that stress generated by thermal expansion between p-side electrode 51 and pad electrode 52 is small. For example, gas such as the air which has lower thermal conductivity than pad electrode 52 and generates relatively low stress with, for example, pad electrode 52 may be used as high thermal resistance part 70. Moreover, a solid material which has lower thermal conductivity than pad electrode 52 and has a thermal expansion coefficient close to the thermal expansion coefficient of, for example, pad electrode 52 may be used as high thermal resistance part 70. A detailed example of such a solid material will be described later on.

In the present embodiment, high thermal resistance part 70 is formed of the air. In other words, the air as high thermal resistance part 70 is filled in pad electrode 52. Consequently, high thermal resistance part 70 can be realized which has higher thermal resistance than pad electrode 52 and can reduce the stress generated due to a difference in the thermal expansion coefficient from pad electrode 52.

Moreover, in a semiconductor laser chip intended for operation with high light output (that is, high output operation), an end surface coat film such as a dielectric multilayer film is formed on a light emission end surface. It is difficult to form the end surface coat film only on the end surface and the end surface coat film also wraps around the top surface of semiconductor laser chip 1. In the aforementioned case, pad electrode 52 is not formed at the end part of semiconductor laser chip 1 in the laser resonator long direction (that is, the Y-axis direction of FIG. 1A), and thus dielectric layer 60 and the end surface coat film may contact each other at the end part of semiconductor laser chip 1 in the longitudinal direction when the end surface coat film wraps around the top surface. At the aforementioned point, when dielectric layer 60 is not formed or the film thickness of dielectric layer 60 is thin for light confinement, the light is influenced by the end surface coat film, which causes light loss. Thus, the film thickness of dielectric layer 60 may be greater than or equal to 100 nm in order to sufficiently confine the light generated at emission layer 30. On the other hand, a too large film thickness of dielectric layer 60 leads to difficulties in forming pad electrode 52, so that the film thickness of dielectric layer 60 may be set to be less than or equal to the height of waveguide part 40a.

Moreover, etching damage may remain and a leak current may be generated on the side surface of waveguide part 40a and flat part 40b in an etching process at time of forming waveguide part 40a, but coating the side surface of waveguide part 40a and flat part 40b with dielectric layer 60 makes it possible to reduce the generation of unnecessary leak current.

N-side electrode 80 is an electrode which is arranged below substrate 10 and an ohmic electrode which makes ohmic contact with substrate 10. N-side electrode 80 is, for example, a laminated film in which a Ti layer, a Pt layer, and an Au layer are laminated on each other in order. The configuration of n-side electrode 80 is not limited to the aforementioned configuration. N-side electrode 80 may be a laminated film in which Ti and Au are laminated on each other.

### [Method for Manufacturing Semiconductor Laser Chip]

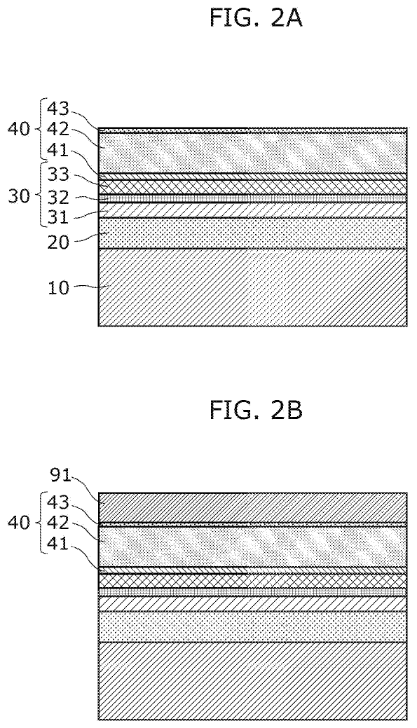

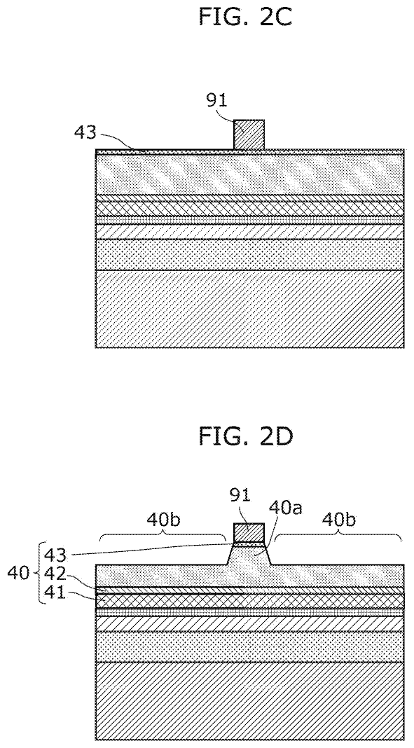

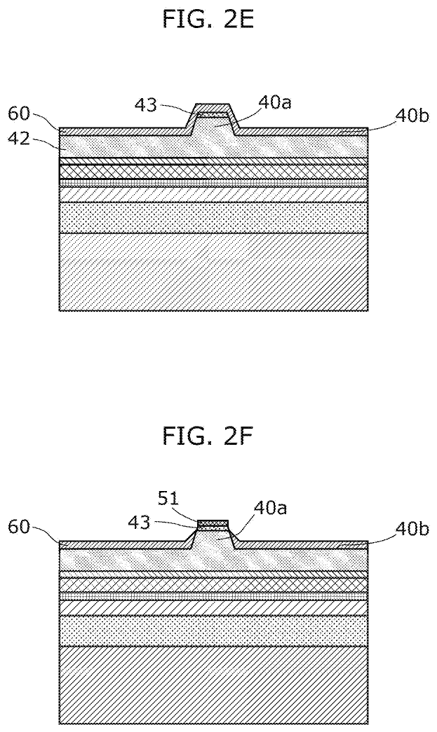

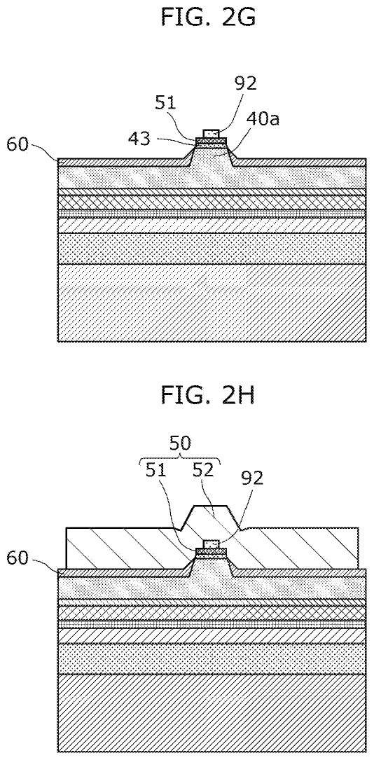

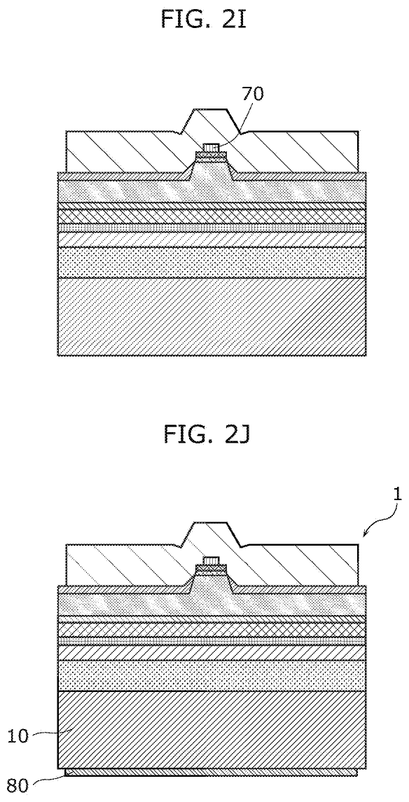

Next, the method for manufacturing semiconductor laser chip 1 according to the present embodiment will be described with reference to FIGS. 2A to 2J. FIGS. 2A to 2J are schematic sectional views respectively illustrating processes in the method for manufacturing semiconductor laser chip 1 according to the present embodiment.

First, as illustrated in FIG. 2A, first semiconductor layer 20, emission layer 30, and second semiconductor layer 40 are sequentially formed on substrate 10 as an n-type hexagonal GaN substrate having surface (0001) as a main surface by use of a metalorganic chemical vapor deposition (MOCVD method). More specifically, an n-side clad layer formed of n-type AlGaN is developed as first semiconductor layer 20 on substrate 10 by 3 μm. Subsequently, n-side light guide layer 31 formed of n-type GaN is developed by 0.2 μm on first semiconductor layer 20. Subsequently, active layer 32 formed of three cycles of a barrier layer formed of InGaN and an InGaN quantum well layer is developed. Subsequently, p-side light guide layer 33 formed of p-type GaN is developed by 0.1 μm. Subsequently, electronic barrier layer 41 formed of AlGaN is developed by 10 nm. Subsequently, p-side clad layer 42 is developed which is composed of a distorted superlattice with a thickness of 0.48 μm obtained by repeatedly forming a p-type AlGaN layer with a film thickness of 1.5 nm and a GaN layer with a film thickness of 1.5 nm for 160 cycles. Subsequently, p-side contact layer 43 formed of P-type GaN is developed by 0.05 μm. Here, for an organic metal raw material containing Ga, Al, and In, for example, trimethylgallium (TMG), trimethylammonium (TMA), and trimethylindium (TMI) are respectively used for the layers. Ammonia (NH₃) is used for a nitrogen raw material.

Next, as illustrated in FIG. 2B, first protective film 91 is formed on second semiconductor layer 40. More specifically, a 300 nm silicon oxide film (SiO₂) is formed as first protective film 91 on p-side contact layer 43 by a plasma chemical vapor deposition (CVD) method using silane (SiH₄).

Note that a method for forming first protective film 91 is not limited to the plasma CVD method and, for example, a well-known film formation method such as a thermal CVD method, a sputtering method, a vacuum vapor deposition method, or a pulse laser film formation method can be used. Moreover, the material used for forming first protective film 91 is not limited to the aforementioned material, and any material such as a dielectric or metal may be used as long as the material has selectivity for the etching of first semiconductor layer 20 to be described later on.

Next, as illustrated in FIG. 2C, first protective film 91 is selectively removed by a photolithography method and an etching method so as to leave first protective film 91 in a band-like shape. Note that first protective film 91 is formed so as to be left on a portion where a waveguide part is formed. Examples of the photolithography method that can be used include: a photolithography method which uses a short wavelength light source; an electron beam lithography method which directly performs drawing with an electron beam; a nanoimprint method; etc. Examples of the etching method include: dry etching through reactive ion etching (RIE) using fluorine-based gas such as CF₄; and wet etching using, for example, hydrofluoric acid (HF) diluted to approximately a ratio of 1:10.

Next, as illustrated in FIG. 2D, as a mask of first protective film 91 formed in a band-like shape, p-side contact layer 43 and p-side clad layer 42 are etched to thereby form waveguide part 40a and flat part 40b at second semiconductor layer 40. For the etching of p-side contact layer 43 and p-side clad layer 42, for example, a dry etching by an RIE method using chlorine-based gas such as Cl₂ may be used.

Next, as illustrated in FIG. 2E, first protective film 91 of a band-like shape is removed by wet etching with hydrofluoric acid or the like and dielectric layer 60 is formed so as to cover p-side contact layer 43 and p-side clad layer 42. That is, dielectric layer 60 is formed on waveguide part 40a and flat part 40b. As dielectric layer 60, a silicon oxide film (SiO₂) with a thickness of 300 nm is formed by a plasma CVD method using silane (SiH₄).

Next, as illustrated in FIG. 2F, only dielectric layer 60 on waveguide part 40a is removed by a photolithography method and wet etching using hydrofluoric acid to expose the top surface of p-side contact layer 43. Then a vacuum vapor deposition method and a lift-off method are used to from p-side electrode 51 formed of Pd and Pt on waveguide part 40a only. More specifically, p-side electrode 51 is formed on p-side contact layer 43 exposed from dielectric layer 60.

Note that the method of forming p-side electrode 51 is not limited to the vacuum vapor deposition method but a sputtering method, a pulse laser film formation method, or the like may also be used. Moreover, a material forming p-side electrode 51 may be a material, such as a Ni/Au-based or a Pt-based material, which makes ohmic contact with second semiconductor layer 40 (p-side contact layer 43).

Next, as illustrated in FIG. 2G, second protective film 92 is formed on only a partial region on p-side electrode 51 in order to form high thermal resistance part 70. As a material of second protective film 92, a material for which the etching speed is faster than the etching speeds for p-side electrode 51 and pad electrode 52 may be used. In the present embodiment, I-line position type photoresist (THMR-8900) manufactured by Tokyo Ohka Kogyo Co., Ltd., was used. When a resist is used as second protective film 92, a film of a resist material can be formed on the entire surface above substrate 10 through the spin coating and can be patterned by use of a photolithography method to thereby form second protective film 92. In the present embodiment, the rotation speed of the spin coating is adjusted to provide the resist with a thickness of 2 μm.

Next, as illustrated in FIG. 2H, pad electrode 52 is formed so as to cover p-side electrode 51, dielectric layer 60, and second protective film 92. More specifically, a negative resist is patterned at portions other than the portion where pad electrode 52 was formed and pad electrode 52 formed of Ti, Pt, and Au is formed on the entire surface above substrate 10 by, for example, a vacuum vapor deposition method, and an unnecessary portion of the electrode is removed by use of a lift-off method. Consequently, pad electrode 52 of a predetermined shape is formed on p-side electrode 51 and dielectric layer 60. As described above, electrode member 50 formed of p-side electrode 51 and pad electrode 52 is formed.

Next, as illustrated in FIG. 2I, second protective film 92 located between p-side electrode 51 and pad electrode 52 is removed to thereby form high thermal resistance part 70 formed of the air. For example, in a case where second protective film 92 is a resist, an organic solvent such as acetone is used as a removal liquid for removing second protective film 92 to remove second protective film 92. In the aforementioned case, the organic solvent (removal liquid) is soaked from the longitudinal end of second semiconductor layer 40 where no pad electrode 52 is formed to thereby remove only second protective film 92. As described above, high thermal resistance part 70 is formed between p-side electrode 51 and pad electrode 52.

Next, as illustrated in FIG. 2J, n-side electrode 80 is formed on a bottom surface of substrate 10. More specifically, n-side electrode 80 formed of Ti, Pt, and Au is formed on the rear surface of substrate 10 by a vacuum vapor deposition method or the like and is patterned by use of a photolithography method and an etching method to thereby form n-side electrode 80 of a predetermined shape. Consequently, semiconductor laser chip 1 according to the present embodiment can be manufactured.

### [Configuration of Semiconductor Laser Element]

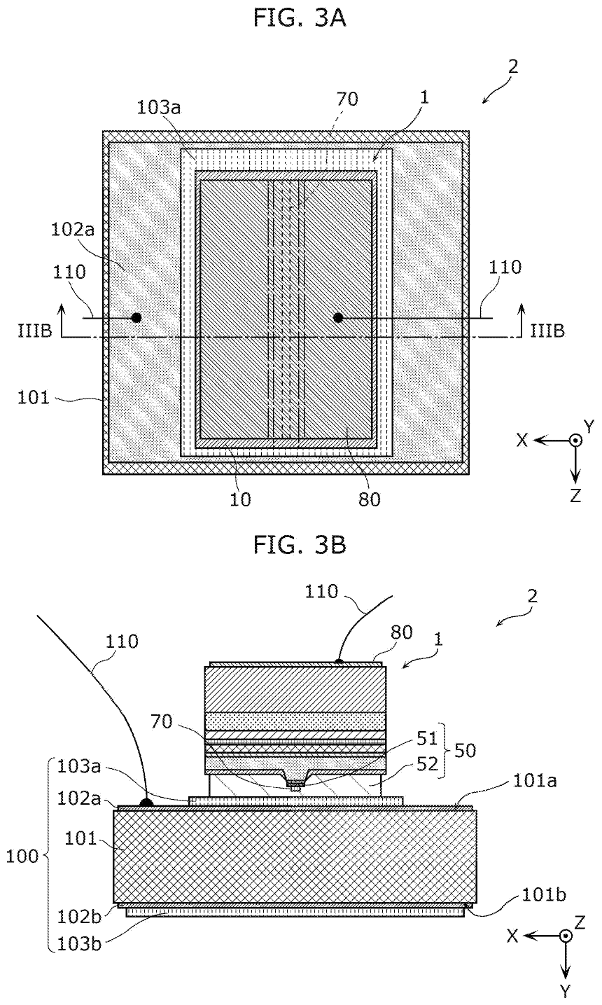

Next, the configuration of the semiconductor laser element according to the present embodiment will be described with reference to FIGS. 3A and 3B. FIGS. 3A and 3B are a schematic plan view and a schematic sectional view illustrating the configuration of semiconductor laser element 2 according to the present embodiment. FIG. 3B is a sectional view of semiconductor laser element 2, taken along line IIIB-IIIB of FIG. 3A.

As illustrated in FIGS. 3A and 3B, semiconductor laser element 2 includes semiconductor laser chip 1 and sub-mount 100.

Sub-mount 100 is a member which has base 101. Sub-mount 100 further has first electrode 102a, second electrode 102b, first solder layer 103a, and second solder layer 103b.

Base 101 is a member which is arranged oppositely to p-side electrode 51 of semiconductor laser chip 1. Base 101 is a main member of sub-mount 100 and has a greatest thickness. Base 101 has first main surface 101a which opposes p-side electrode 51 of semiconductor laser chip 1. In the present embodiment, first electrode 102a and first solder layer 103a are arranged on first main surface 101a in order from base 101 side. Moreover, base 101 has second main surface 101b on the rear side of first main surface 101a. Second electrode 102b and second solder layer 103b are arranged on second main surface 101b in order from base 101 side. The shape of base 101 is not specifically limited but is plate-shaped and more specifically rectangular parallelepiped in the present embodiment.

The material of base 101 is not specifically limited and may be formed of a material, for example, a ceramic such as aluminum nitride (AlN) or silicon carbide (SiC), a diamond (C) formed by CVD, a simple metal such as Cu or Al, or an alloy such as CuW, which has thermal conductivity equal to or greater than the thermal conductivity of semiconductor laser chip 1.

First electrode 102a is one example of a conductive member which is arranged between p-side electrode 51 and base 101 and is arranged on first main surface 101a of base 101. Second electrode 102b is arranged on second main surface 101b of base 101. First electrode 102a and second electrode 102b are each, for example, a laminated film in which Ti with a film thickness of 0.1 μm, Pt with a film thickness of 0.2 μm, and Au with a film thickness of 0.2 μm are laminated on each other in order from base 101 side.

First solder layer 103a is one example of a conductive member which is arranged between p-side electrode 51 and base 101 and is arranged on first electrode 102a. Second solder layer 103b is arranged on second electrode 102b. First solder layer 103a and second solder layer 103b are, for example, each a eutectic solder which consists of a gold tin alloy containing Au with a composition ratio of 70% and Sn with a composition ratio of 30%.

Semiconductor laser chip 1 is mounted on sub-mount 100. In the present embodiment, the p-side of semiconductor laser chip 1 is mounted so as to be connected to sub-mount 100, that is, junction-down mounting is performed, and thus pad electrode 52 of semiconductor laser chip 1 is connected to first solder layer 103a of sub-mount 100. That is, pad electrode 52 is arranged between p-side electrode 51 and base 101.

Note that in a case where a gold tin solder is used for mounting on first solder layer 103a as is the case with the present embodiment, the gold tin solder causes eutectic reaction with Au of pad electrode 52 and Au of first electrode 102a, which may therefore make it difficult to judge a border.

Moreover, wire 110 is connected to each of pad electrode 52 of semiconductor laser chip 1 and first electrode 102a of sub-mount 100 by wire bonding. Consequently, a current can be supplied to semiconductor laser chip 1 via wire 110.

Note that sub-mount 100 may be mounted on a metal package such as, for example, a CAN package for the purpose of improving the heat dissipation and simplifying handling, although not illustrated.

### [Action and Effects of Semiconductor Laser Element]

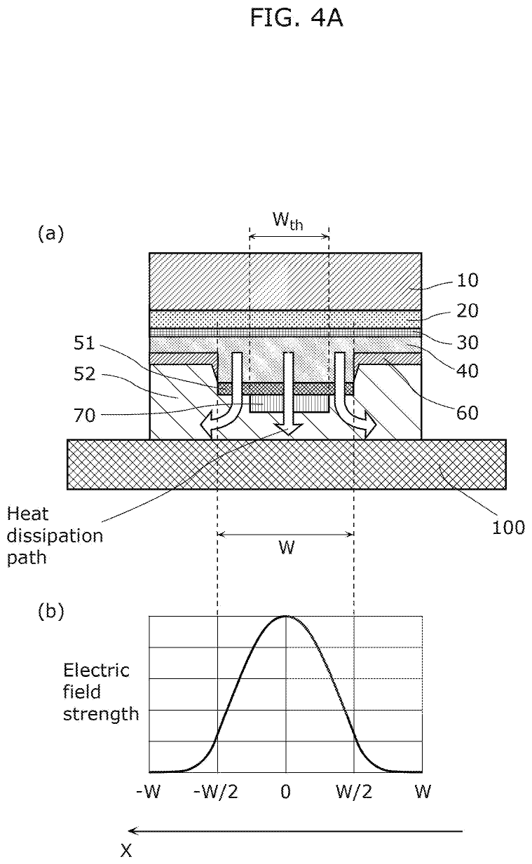

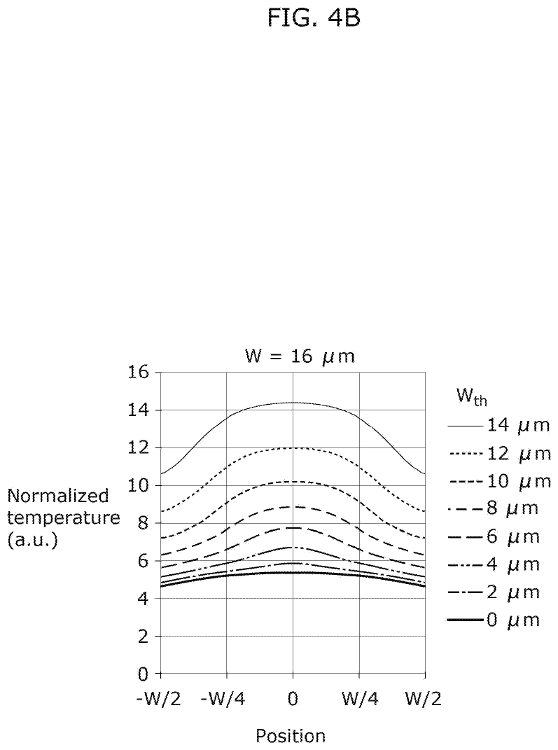

Next, the action and effects of semiconductor laser chip 1 according to the present embodiment will be described with reference to FIGS. 4A and 4B. FIG. 4A is a diagram illustrating a heat dissipation path and electric field strength distribution of laser light in a fundamental transverse mode in semiconductor laser element 2 according to the present embodiment. A sectional view (a) in FIG. 4A is a diagram illustrating a mode of mounting semiconductor laser chip 1 onto sub-mount 100 in a simplified manner. A graph (b) in FIG. 4A is a diagram illustrating calculation results of the electric field strength distribution of the laser light in the fundamental transverse mode in semiconductor laser element 2. FIG. 4B is a diagram illustrating calculation results of temperature distribution of emission layer 30 at a portion with a width W immediately below waveguide part 40a according to the present embodiment.

In semiconductors, the refractive index typically increases with an increase in the temperature while the refractive index decreases with an increase in the carrier density. A horizontal transverse mode in the wide stripe structure is affected by the refractive index distribution in waveguide part 40a, so that it is important to control the temperature distribution and the carrier distribution in waveguide part 40a in order to maintain fundamental transverse operation during high output operation. For example, when the temperature of a central part of waveguide part 40a in a width direction (an X-axis direction of FIG. 4A) has become high, the refractive index of the central part of waveguide part 40a in the width direction more increases than the refractive index of the end part of waveguide part 40a in the width direction and the horizontal transverse mode in which the light intensity is strong at the central part of waveguide part 40a in the width direction becomes preferential. On the other hand, with a decrease in the temperature at the central part of waveguide part 40a in the width direction, the refractive index at the central part of waveguide part 40a in the width direction more decreases than the refractive index at the end part in the width direction and the refractive index at the end part of waveguide part 40a in the width direction more increases, so that the horizontal transverse mode in which the light intensity at the end part of waveguide part 40a in the width direction is strong becomes preferential.

In order to provide a higher temperature at the central part of waveguide part 40a in the width direction than at the end part of waveguide part 40a in the width direction, the heat dissipation performance at the central part of the waveguide part in the width direction may be deteriorated. Specifically, a structure with high thermal resistance can be provided on a heat dissipation path at the central part of the waveguide part in the width direction to thereby provide a higher temperature at the central part of the waveguide part than at the end part thereof. That is, providing a material with higher thermal resistance (that is, lower thermal conductivity) than electrode member 50 between waveguide part 40a and base 101 of sub-mount 100 makes it possible to provide a higher temperature at the central part of waveguide part 40a in the width direction than at the end part thereof.

In FIG. 4A, a sectional view (a) illustrates a mode of mounting semiconductor laser chip 1 according to the present embodiment in a simplified manner. In the aforementioned mode, which is a mode in which p-side electrode member 50 is connected to sub-mount 100, that is, junction-down mounting, a heat generated at semiconductor laser chip 1 is dissipated from electrode member 50 of a p-side to sub-mount 100. In the sectional view (a) in FIG. 4A, a heat dissipation path for the heat generated at semiconductor laser chip 1 is indicated by arrows. Since high thermal resistance part 70 lies in the middle of the heat dissipation path at the central part of waveguide part 40a in the width direction, the heat dissipation at the central part of waveguide part 40a in the width direction deteriorates and the temperature at the central part of waveguide part 40a in the width direction increases. The center of high thermal resistance part 70 is arranged so as to coincide with the center of waveguide part 40a in the width direction. In other words, high thermal resistance part 70 is arranged above (below in FIG. 4A) the center of p-side electrode 51 in the width direction. Specifically, waveguide part 40a and high thermal resistance part 70 are horizontally symmetrical to the center of waveguide part 40a in the width direction in the cross section of semiconductor laser chip 1. Consequently, it is possible to bring the peak of the distribution in the fundamental transverse mode and the peak of the temperature distribution at the waveguide part into agreement with each other, thus making it possible to promote the fundamental transverse mode operation. Here, where the width of high thermal resistance part 70 is defined as Wₜₕ and the width of waveguide part 40a, that is, the width of p-side electrode 51 is defined as W, relation Wₜₕ<W holds. That is, the width of the high heat resistance part is smaller than the width of the waveguide part. In case of Wₜₕ<W, high thermal resistance part 70 does not lie on the heat dissipation path from the end part of waveguide part 40a in the width direction, and it is thus possible to increase a temperature difference between the central part and the end part of waveguide part 40a in the width direction. That is, it is possible to increase a refractive index difference between the central part and the end part of waveguide part 40a in the width direction.

As described above, high thermal resistance part 70 is arranged above the center of p-side electrode 51 in the width direction in the present embodiment. Here, a configuration denoted by a description with the center of p-side electrode 51 in the width direction includes not only a configuration such that complete agreement with the center of p-side electrode 51 in the width direction is achieved but also a configuration such that substantial agreement therewith is achieved. For example, the configuration denoted by the description with the center of p-side electrode 51 in the width direction may include a configuration such that a shift occurs from the center by a degree less than or equal to approximately 10 percent of the width of p-side electrode 51.

Moreover, high thermal resistance part 70 contacts p-side electrode 51 in the present embodiment. Consequently, effect of preventing heat dissipation from p-side electrode 51 and waveguide part 40a by high thermal resistance part 70 can be improved.

In FIG. 4A, a graph (b) illustrates calculation results of electric field strength in the fundamental transverse mode. As illustrated in the graph (b) in FIG. 4A, the light distribution in the fundamental transverse mode has a peak at the central part of waveguide part 40a in the width direction, and thus a structure such that the temperature at the central part of waveguide part 40a in the width direction increases is advantageous for maintaining the fundamental transverse mode operation.

FIG. 4B is a graph illustrating calculation results of temperature distribution at active layer 32. The temperature distribution illustrated in FIG. 4B is obtained by providing a 1 W heat generation source at waveguide part 40a and solving a heat conductance equation. The calculation is made where the thermal conductivity of the materials included in semiconductor laser chip 1 is 130 W/mK for GaN, 80 W/mK for p-side electrode 51, 60 W/mK for pad electrode 52, and 1.4 W/mK for SiO₂, and the width W of waveguide part 40a is 16 μm. Moreover, assuming a case where the material of high thermal resistance part 70 is the air, the thermal conductivity is 0.024 W/mK. Moreover, the calculation is performed while varying the width Wₜh of high thermal resistance part 70 from 2 μm to 14 μm every 2 μm. Moreover, for the purpose of comparison, calculation is performed for a case of a conventional structure where Wₜₕ=0 μm, that is, where semiconductor laser chip includes no high thermal resistance part.

It has been found from the calculation results that the temperature is highest at the central part of the waveguide part in the width direction and the temperature decreases with a decrease in the distance from the end part. The aforementioned phenomenon occurs because the widths of pad electrode 52 and sub-mount 100 are sufficiently greater than the width W of the waveguide part serving as a heat generation source and thus the temperature of waveguide part 40a in the width direction decreases due to the effect of thermal diffusion at pad electrode 52 and sub-mount 100 in a horizontal direction (that is, the X-axis direction). It is also found that the temperature at a portion where high thermal resistance part 70 is provided more increases. The aforementioned phenomenon is caused by a deterioration in the heat dissipation performance at the central part of waveguide part 40a in the width direction by high thermal resistance part 70. A temperature difference between the center and the end part of the waveguide part in the conventional structure (that is, Wₜₕ=0) is 0.7 degrees Celsius, while the temperature difference is 2.5 degrees Celsius when the width Wₜₕ of high thermal resistance part 70 is, for example, 8 μm. The fundamental transverse mode is more preferential for a greater temperature difference. As described above, with semiconductor laser element 2 according to the present embodiment, a refractive index distribution in which the fundamental transverse mode is preferential can be formed at waveguide part 40a by high thermal resistance part 70, which can therefore improve the ratio of the fundamental transverse mode in the laser light even during high output operation.

In the present embodiment, when the width Wₜₕ of high thermal resistance part 70 is 8 μm, that is, when the width Wₜₕ of high thermal resistance part 70 is 0.5 times the width W of waveguide part 40a, the most favorable results were obtained for the ratio of the fundamental transverse mode and the laser light output intensity. Moreover, when the width Wₜₕ of the high thermal resistance part is greater than or equal to 0.375 times the width W of waveguide part 40a (Wₜₕ=6 μm in the present embodiment) and less than or equal to 0.625 times (Wₜₕ=10 μm in the present embodiment) the width W of waveguide part 40a, the particularly most favorable results were obtained for the ratio of the fundamental transverse mode and the laser light output intensity.

Note that the high thermal resistance of high thermal resistance part 70 means that the thermal resistance is high for the surrounding materials. The thermal conductivity of pad electrode 52 and p-side electrode 51 is 60 to 80 W/mK, and thus in order to obtain the effects of the present embodiment, the thermal conductivity of high thermal resistance part 70 may be less than or equal to 8 W/mK which is one digit smaller than the thermal conductivity of pad electrode 52 and p-side electrode 51.

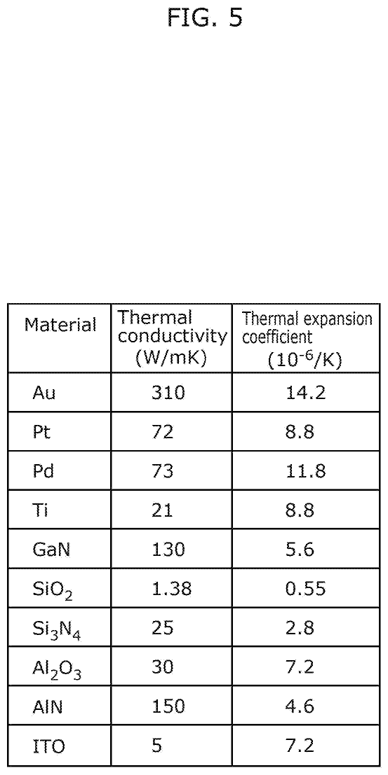

Moreover, upon filling high thermal resistance part 70 in the metal, the thermal expansion coefficient is important. The temperature greatly increases during the high output operation, and thus a large thermal expansion coefficient difference between high thermal resistance part 70 and electrode member 50 causes peeling, causing a problem that the properties of semiconductor laser element 2 greatly deteriorates. Here, the materials forming high thermal resistance part 70 will be described with reference to FIG. 5. FIG. 5 is a table illustrating the thermal conductivity and thermal expansion coefficients of the materials used for semiconductor laser element 2 according to the present embodiment and the materials that can form high thermal resistance part 70. In the present embodiment, the air is used as high thermal resistance part 70 but gas other than the air may also be used. For example, gas such as nitrogen may also be used as high thermal resistance part 70.

### Embodiment 2

A semiconductor laser element according to Embodiment 2 will be described. Illustrated in Embodiment 1 is the structure in which high thermal resistance part 70 is provided between pad electrode 52 and p-side electrode 51. The present embodiment will be described, referring to a structure in which high thermal resistance part 70 is provided through a simpler technique. The semiconductor laser element according to the present embodiment differs from semiconductor laser element 2 according to Embodiment 1 mainly in the configuration of high thermal resistance part 70a. Hereinafter, the semiconductor laser element according to the present embodiment will be described, focusing on the difference from semiconductor laser element 2 according to Embodiment 1.

### [Configuration of Semiconductor Laser Element]

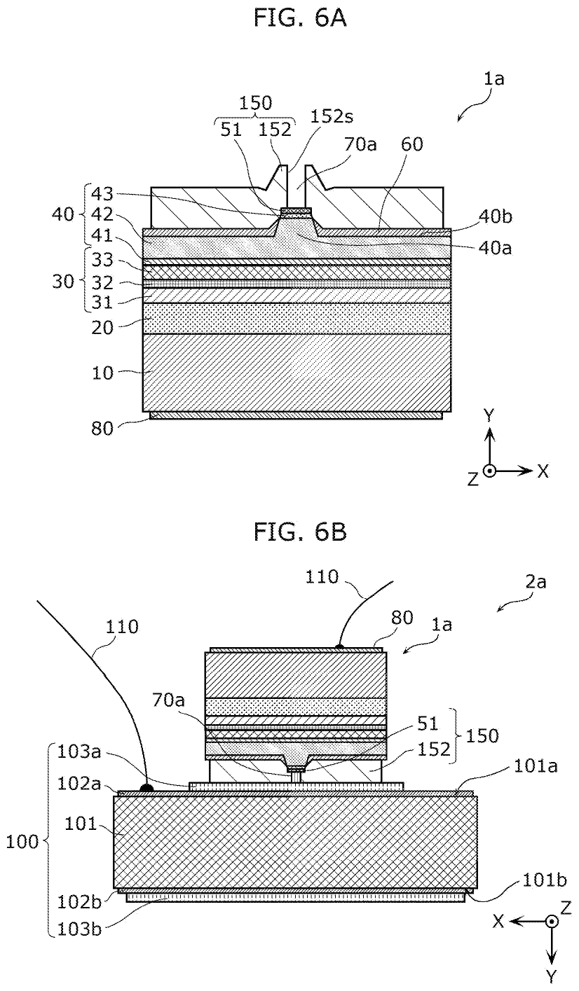

First, the configurations of a semiconductor laser chip and the semiconductor laser element according to the present embodiment will be described with reference to FIGS. 6A and 6B. FIG. 6A is a schematic sectional view illustrating the configuration of semiconductor laser chip 1a according to the present embodiment. FIG. 6B is a schematic sectional view illustrating the configuration of semiconductor laser element 2a according to the present embodiment. As in FIG. 1B, cross sections perpendicular to the laser resonator long direction of semiconductor laser chip 1a and semiconductor laser element 2a are illustrated in FIGS. 6A and 6B.

As illustrated in FIG. 6A, semiconductor laser chip 1a according to the present embodiment includes substrate 10, first semiconductor layer 20, emission layer 30, second semiconductor layer 40, electrode member 150, and high thermal resistance part 70a, as is the case with semiconductor laser chip 1 according to Embodiment 1. Semiconductor laser chip 1a according to the present embodiment differs from semiconductor laser chip 1 according to Embodiment 1 in the configurations of pad electrode 152 of electrode member 150 and high thermal resistance part 70a.

Electrode member 150 according to the present embodiment has p-side electrode 51 and pad electrode 152. P-side electrode 51 has the same configuration as the configuration of p-side electrode 51 according to Embodiment 1. Pad electrode 152 is divided into two on p-side electrode 51 on the cross section perpendicular to the laser resonator long direction (the Z-axis direction of FIG. 6A) as illustrated in FIGS. 6A and 6B. That is, slit part 152s is formed at pad electrode 152.

High thermal resistance part 70a is a void part which is arranged between the two divided pad electrodes 152 (that is, at slit part 152s). In other words, high thermal resistance part 70a is a void part which is arranged in an inner region of pad electrode 152. In the present embodiment, high thermal resistance part 70a is formed of the air.

As illustrated in FIG. 6B, semiconductor laser element 2a according to the present embodiment includes semiconductor laser chip 1a and sub-mount 100. Sub-mount 100 according to the present embodiment has the same configuration as the configuration of sub-mount 100 according to Embodiment 1. As is the case with semiconductor laser element 2 according to Embodiment 1, semiconductor laser chip 1a is junction-down mounted on sub-mount 100. That is, sub-mount 100 is arranged oppositely to p-side electrode 51 and pad electrode 152 is arranged between p-side electrode 51 and base 101 of sub-mount 100.

In the present embodiment, high thermal resistance part 70a extends from p-side electrode 51 to sub-mount 100. In other words, semiconductor laser element 2a according to the present embodiment includes a first solder layer which is arranged between pad electrode 152 and base 101 as one example of a conductive member arranged above p-side electrode 51, and high thermal resistance part 70a extends from p-side electrode 51 to first solder layer 103a. Even semiconductor laser element 2a with such a configuration provides the same effect as the effect provided by semiconductor laser element 2 according to Embodiment 1.

### [Method for Manufacturing Semiconductor Laser Element]

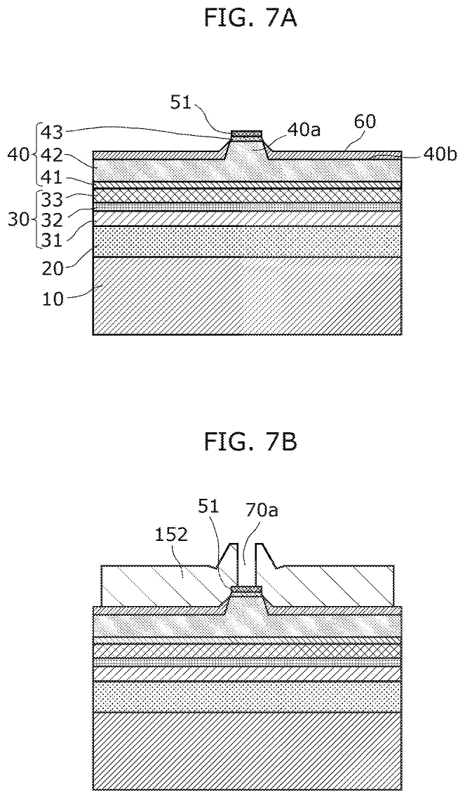

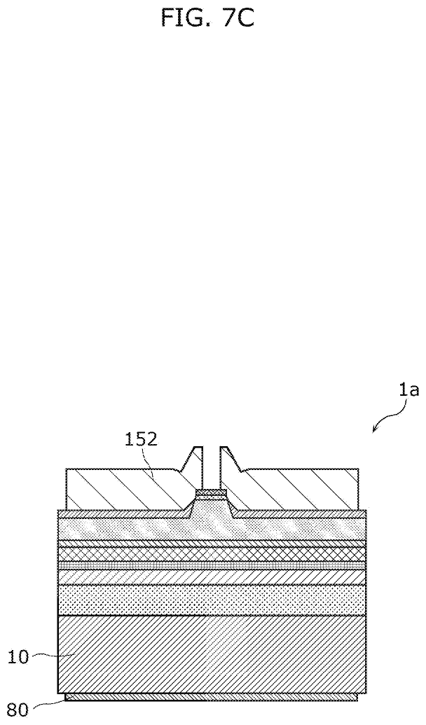

Next, the method for manufacturing semiconductor laser element 2a according to the present embodiment will be described. The method for manufacturing semiconductor laser element 2a according to the present embodiment is the same as the method for manufacturing semiconductor laser element 2 according to Embodiment 1 except for the method for manufacturing semiconductor laser chip 1a, and thus the method for manufacturing semiconductor laser chip 1a will be described with reference to FIGS. 7A to 7C. FIGS. 7A to 7C are schematic sectional views illustrating processes of the method for manufacturing semiconductor laser chip 1a according to the present embodiment.

A point included in points of the method for manufacturing semiconductor laser chip 1a according to the present embodiment and different from the method for manufacturing semiconductor laser chip 1 according to Embodiment 1 will be described.

First, as illustrated in FIG. 7A, first semiconductor layer 20, emission layer 30, second semiconductor layer 40, and p-side electrode 51 are laminated on substrate 10. The diagram illustrated in FIG. 7A is the same as FIG. 2F illustrating processes of the method for manufacturing semiconductor laser chip 1 according to Embodiment 1. That is, a laminated body as illustrated in FIG. 7A is formed in the present embodiment through the same processes as the processes described in Embodiment 1 with reference to FIGS. 2A to 2F.

Subsequently, as illustrated in FIG. 7B, pad electrode 152 is formed by use of a lift-off method at a desired position on p-side electrode 51 in a manner such that pad electrode 152 is not provided. As a result of remaining a resist even on part of p-side electrode 51 upon the patterning of a photoresist, a region where pad electrode 152 is not formed can be created in the aforementioned portion. Next, as is the case with Embodiment 1, as illustrated in FIG. 7C, n-side electrode 80 is formed at substrate 10.

Consequently, semiconductor laser chip 1a according to the present embodiment can be manufactured. Moreover, semiconductor laser chip 1a manufactured in the manner described above can be mounted on sub-mount 100 to thereby manufacture semiconductor laser element 2a.

Moreover, high thermal resistance part 70a can be formed only by patterning pad electrode 152 in the present embodiment, which can therefore ease the manufacture.

### Embodiment 3

A semiconductor laser element according to Embodiment 3 will be described. The high thermal resistance parts are respectively formed at the semiconductor laser element chips in Embodiments 1 and 2. The semiconductor laser element according to the present embodiment has a high thermal resistance part formed on a sub-mount. The semiconductor laser element according to the present embodiment will be described, focusing on a difference from semiconductor laser element 2 according to Embodiment 1.

### [Configuration of Semiconductor Laser Element]

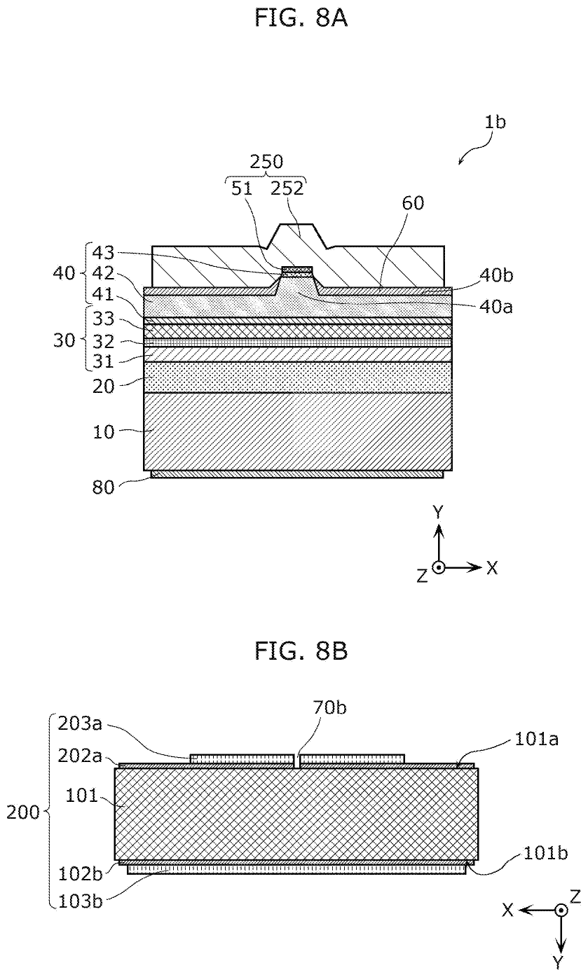

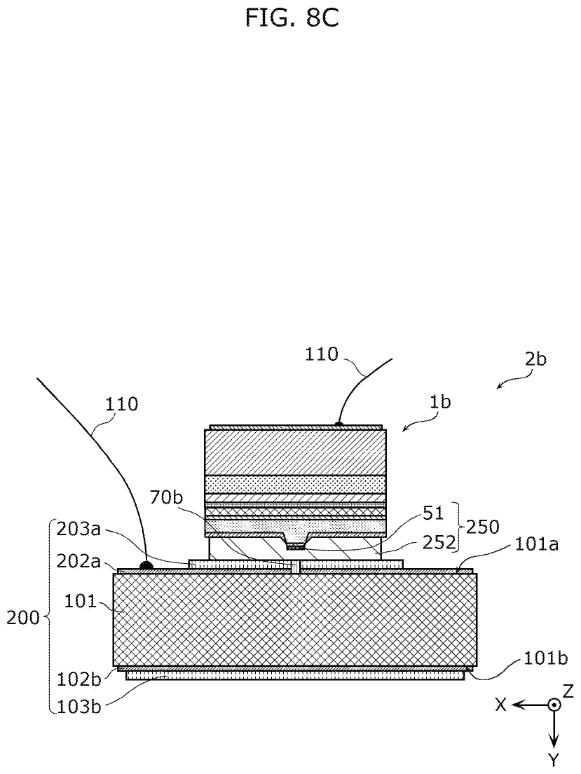

The configuration of the semiconductor laser element according to the present embodiment will be described with reference to FIGS. 8A to 8C. FIG. 8A is a schematic sectional view illustrating the configuration of semiconductor laser chip 1b according to the present embodiment. As illustrated in FIG. 8A, semiconductor laser chip 1b differs from the respective semiconductor laser chips according to Embodiments 1 and 2 in that electrode member 250 has no high thermal resistance part. That is, semiconductor laser chip 1b according to the present embodiment has the same structure as the structure of conventional semiconductor laser chips. Electrode member 250 according to the present embodiment has p-side electrode 51 and pad electrode 252. No high thermal resistance part is filled in pad electrode 252.

FIG. 8B is a schematic sectional view illustrating the configuration of sub-mount 200 according to the present embodiment. Sub-mount 200 according to the present embodiment has base 101, first electrode 202a, second electrode 102b, first solder layer 203a, second solder layer 103b, and high thermal resistance part 70b. Base 101, second electrode 102b, and second solder layer 103b according to the present embodiment respectively have the same configurations as the configurations of base 101, second electrode 102b, and second solder layer 103b according to Embodiments 1 and 2.

First electrode 202a and first solder layer 203a according to the present embodiment are each divided into two on the cross section perpendicular to the laser resonator long direction (the Z-axis direction of FIG. 8B). High thermal resistance part 70b is a void part which is arranged between two divided first electrodes 202a and between two divided first solder layers 203a. In other words, high thermal resistance part 70b is a void part which is arranged in an inner region of first electrode 202a and first solder layer 203a. In the present embodiment, high thermal resistance part 70b is formed of the air.

FIG. 8C is a schematic sectional view illustrating the configuration of semiconductor laser element 2b according to the present embodiment. As illustrated in FIG. 8C, semiconductor laser element 2b according to the present embodiment includes semiconductor laser chip 1b and sub-mount 200. As is the case with semiconductor laser elements according to Embodiments 1 and 2, semiconductor laser chip 1b is junction-down mounted on sub-mount 200. That is, sub-mount 200 is arranged oppositely to p-side electrode 51 and pad electrode 252 is arranged between p-side electrode 51 and base 101 of sub-mount 200. Here, p-side electrode 51 is arranged at a position opposing high thermal resistance part 70b. More specifically, high thermal resistance part 70b is arranged at the center of p-side electrode 51 in the width direction (the X-axis direction of FIG. 8C). In the present embodiment, each of pad electrode 252, first electrode 202a, and first solder layer 203a is one example of a conductive member which is arranged between p-side electrode 51 and base 101.

As described above, high thermal resistance part 70b contacts base 101 in the present embodiment. Even semiconductor laser element 2b having such a configuration provides the same effects as the effects provided by the semiconductor laser elements according to Embodiments 1 and 2.

### Embodiment 4

A semiconductor laser element according to Embodiment 4 will be described. The semiconductor laser element according to the present embodiment differs from semiconductor laser element 2 according to Embodiment 1 in that the width of the high thermal resistance part varies in accordance with the position of the laser resonator long direction (the longitudinal direction of the waveguide part). Hereinafter, the configuration of the semiconductor laser element according to the present embodiment will be described, focusing on a difference from semiconductor laser element 2 according to Embodiment 1.

### [Configuration of Semiconductor Laser Element]

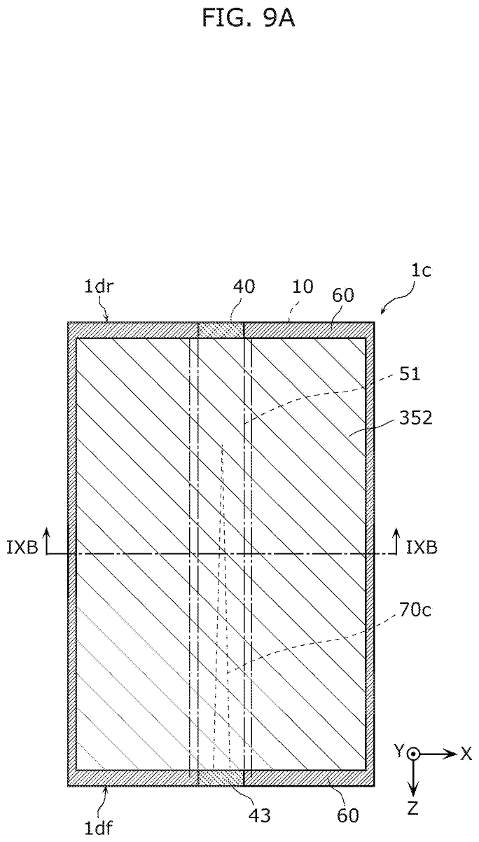

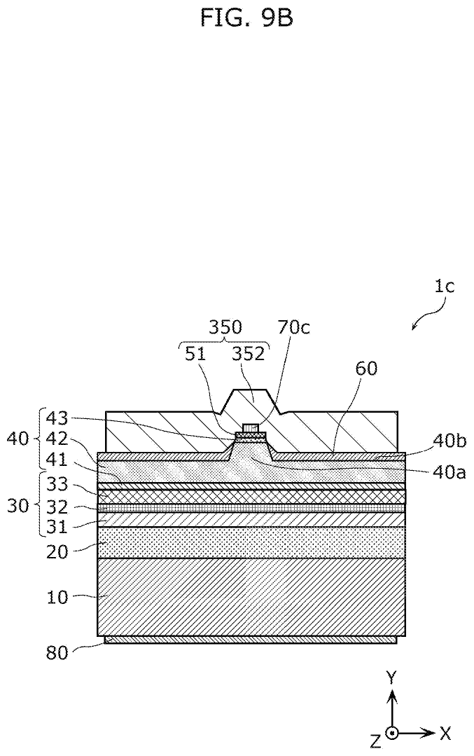

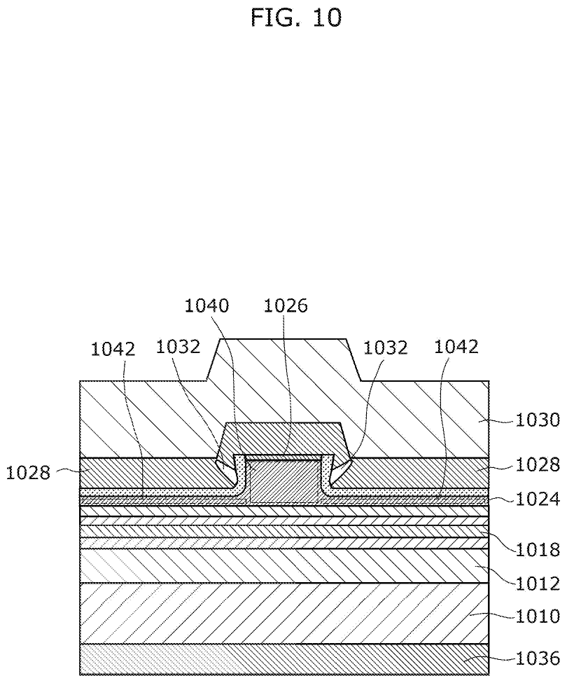

The configuration of the semiconductor laser element according to the present embodiment will be described. The semiconductor laser element according to the present embodiment differs from semiconductor laser element 2 according to Embodiment 1 in a semiconductor laser chip but is identical to semiconductor laser element 2 according to Embodiment 1 in the configuration of sub-mount 100. Thus, semiconductor laser chip 1c included in the semiconductor laser element according to the present embodiment will be described while a description of the sub-mount will be omitted. FIG. 9A is a schematic plan view illustrating the configuration of semiconductor laser chip 1c according to the present embodiment. FIG. 9A illustrates a plan view of substrate 10 of semiconductor laser chip 1c. FIG. 9B is a schematic sectional view illustrating the configuration of semiconductor laser chip 1c according to Embodiment 4. FIG. 9B illustrates a cross section of semiconductor laser chip 1c, taken along line IXB-IXB of FIG. 9A.

As illustrated in FIG. 9B, semiconductor laser chip 1c according to the present embodiment has substrate 10, first semiconductor layer 20, emission layer 30, second semiconductor layer 40, electrode member 350, dielectric layer 60, high thermal resistance part 70c, and n-side electrode 80. Semiconductor laser chip 1c also has: front side end surface 1df which is one of end surfaces in a transmission direction of light generated at emission layer 30 and from which the light is emitted; and rear side end surface 1dr which is another one of the end surfaces in the transmission direction of the light and has higher light reflectance than front side end surface 1df. Electrode member 350 has p-side electrode 51 and pad electrode 352. Pad electrode 352 differs from pad electrode 52 according to Embodiment 1 in that a portion corresponding to high thermal resistance part 70c is different, and pad electrode 352 is the same as pad electrode 52 according to Embodiment 1 in other points.

As illustrated in FIG. 9A, the width of high thermal resistance part 70c according to the present embodiment varies in accordance with the position of the laser resonator long direction (that is, the Z-axis direction of FIG. 9A). More specifically, the width of high thermal resistance part 70c increases with a decrease in distance from front side end surface 1df and decreases with a decrease in distance from rear side end surface 1dr. As illustrated in FIG. 9A, high thermal resistance part 70c does not have to be formed at a position near rear side end surface 1dr.

In order to realize higher output, a typical semiconductor laser chip uses a structure in which one of the resonator end surfaces has high reflectance and another one of the resonator end surfaces has low reflectance. With the aforementioned structure, the light density in the laser resonator long direction varies. The light density is high at a position near the resonator end surface with low reflectance. The transverse mode selection is more effective at a position where the light density is high, and thus the transverse mode can be more effectively controlled by providing high thermal resistance part 70c at a position near front side end surface 1df with relatively high light density. Moreover, the heat dissipation can be ensured by providing no high thermal resistance part 70c at a position near rear side end surface 1dr with the relatively low light density (or by reducing the width of high thermal resistance part 70c).

As described above, with the semiconductor laser element according to the present embodiment, it is possible to improve the ratio of the fundamental transverse mode in laser light and also ensure the heat dissipation. It is possible to increase the ratio of the fundamental mode in laser light even during high output operation in which the heat generation amount is large.

### VARIATION AND OTHERS

The semiconductor laser elements according to the present disclosure have been described above based on the respective embodiments, but the present disclosure is not limited to the embodiments described above.

For example, waveguide part 40a of second semiconductor layer 40 has a ridged shape in the embodiments described above, but the configuration of the waveguide part is not limited to such a shape. For example, the waveguide part may not be projected in a direction away from the emission layer. In the aforementioned case, for example, a groove may be formed at the end part of the waveguide part in the width direction and the aforementioned groove may be filled with a dielectric. The semiconductor laser element having such a configuration also provides the same effects as the effects provided by the semiconductor laser elements according to the embodiments described above. Further, with such a configuration, it is possible to suppress a force added to the second semiconductor layer from focusing on the waveguide part upon mounting the semiconductor laser chip on the sub-mount. Therefore, it is possible to reduce damage to the waveguide part upon the mounting.

Moreover, the semiconductor laser element includes the semiconductor laser chip formed of a nitride semiconductor in each of the embodiments described above, but the semiconductor laser chip may be formed of a semiconductor material other than the nitride semiconductor.

Moreover, the present disclosure also includes: a mode obtained by making various modifications, conceivable to those skilled in the art, to the embodiments described above; and a mode realized by combining together the components and the functions in the embodiments described above in a desired manner within a range not departing from the spirits of the present disclosure.

For example, Embodiment 2 and Embodiment 3 may be combined together. That is, the high thermal resistance part may extend from the p-side electrode of the semiconductor laser chip to the base of the sub-mount.

Moreover, the configuration of Embodiment 4 may be applied to the high thermal resistance part according to Embodiment 2 or Embodiment 3.

### INDUSTRIAL APPLICABILITY

The semiconductor laser element according to the present disclosure can be used as a light source for, for example, an image display device, an illumination, or an industrial device, and is specifically useful as a light source for a device which requires relatively high light output.

1. A semiconductor laser element, comprising:
a first semiconductor layer of a first conductive type;
an emission layer which is arranged above the first semiconductor layer;
a second semiconductor layer of a second conductive type which is arranged above the emission layer and includes a waveguide part through which light generated at the emission layer is transmitted;
an electrode which is arranged above the waveguide part;
a base which is arranged oppositely to the electrode;
a conductive member which is arranged between the electrode and the base; and
a void part which is arranged in an inner region of the conductive member and has higher thermal resistance than the conductive member.

2. The semiconductor laser element according to claim 1, wherein
the second semiconductor layer further includes a flat part which is arranged adjacently to the waveguide part, and
the waveguide part is projected from the flat part in a direction away from the emission layer.

3. The semiconductor laser element according to claim 1, wherein
a width of the void part is smaller than a width of the waveguide part.

4. The semiconductor laser element according to claim 1, wherein
a width of the void part is greater than or equal to 0.375 times and less than or equal to 0.625 times a width of the waveguide part.

5. The semiconductor laser element according to claim 1, further comprising:
a front side end surface which is one of end surfaces in a transmission direction of the light and from which the light is emitted; and
a rear side end surface which is another one of the end surfaces in the transmission direction of the light and has higher reflectance of the light than the front side end surface, wherein
a width of the void part increases with a decrease in distance from the front side end surface.

6. The semiconductor laser element according to claim 1, wherein
the void part is formed of air.

7. The semiconductor laser element according to claim 1, wherein
the void part is arranged above a center of the electrode in a width direction.

8. The semiconductor laser element according to claim 1, wherein
the void part contacts the electrode.

9. The semiconductor laser element according to claim 8, further comprising:
a solder layer which is arranged between the base and the conductive member, wherein
the void part extends from the electrode to the solder layer.

10. The semiconductor laser element according to claim 1, wherein
the void part contacts the base.
